(19) United States
(12) Patent Application Publication
(10) Pub. No.: US 2013/0126934 A1
(43) Pub. Date: May 23, 2013

(54) BONDING WIRE FOR SEMICONDUCTOR DEVICES

(71) Applicant: Heraeus Materials Technology GmbH & Co. KG, Hanau (DE)

(72) Inventors: Eun-Kyun CHUNG, Nam-Ku (KR); Jae-Sung RYU, Bucheon-si (KR); Yong-Deok TARK, Namdong-gu (KR)

(73) Assignee: Heraeus Materials Technology GmbH & Co. KG, Hanau (DE)

(21) Appl. No.: 13/680,871

(22) Filed: Nov. 19, 2012

(30) Foreign Application Priority Data
Nov. 21, 2011 (KR) 10-2011-0121882

(51) Int. Cl. H01L 33/62; C22C 5/06; C22C 5/08; B21C 3/00

(52) U.S. Cl. CPC H01L 33/62; B21C 3/00; C22C 5/06; C22C 5/08
USPC 257/99; 72/274; 420/501; 420/506; 420/502; 420/505; 420/504; 420/503

(57) ABSTRACT

A bonding wire for semiconductor devices and a method of manufacturing the wire are provided. The bonding wire contains at least one element selected from zinc, tin, and nickel in an amount of 5 ppm to 10 wt %, the remainder containing silver and inevitable impurities. The method involves pouring a silver alloy according to the invention into a mold and melting the silver alloy, continuously casting the melted silver alloy, and drawing the continuously casted silver alloy.

### BACKGROUND OF THE INVENTION

1. Field of the Invention

The present invention relates to a bonding wire and, more particularly, to a bonding wire for semiconductor devices, and to a light-emitting diode (LED) package using the same, in which silver (Ag) is used as a main ingredient.

2. Description of the Related Art

A bonding wire is a metal line for electrically connecting an IC chip or an LED chip and a lead frame, and is generally made of gold (Au).

In order to reduce costs when bonding wires are fabricated, and because of a sudden rise in recent gold prices worldwide, attempts have been made to use copper (Cu) wires or copper wires on which palladium (Pd) is coated for bonding wires. Some manufacturers mass-produce copper wires, but continued research is being performed on alloy wires based on gold because the characteristics of copper are not as good as those of gold.

For example, research is being performed on gold-silver alloy wires based on gold. Gold-silver alloy wires are advantages in that costs can be reduced because silver (i.e., an alloy element) has excellent electrical conductivity and because silver and gold form a complete solid solution.

However, there is a limit to the extent of possible cost reduction because a large amount of gold is contained in the gold-silver alloy wires. Furthermore, copper wires and copper wires coated with palladium cannot be used in LED packages because reflectivity, the most important function of an LED, is deteriorated.

Accordingly, there is an urgent need for the development of a bonding wire made of a new material which exhibits excellent reliability and reflectivity characteristics while reducing costs.

### BRIEF SUMMARY OF THE INVENTION

The present invention provides a bonding wire for semiconductor devices and an LED package using the same, in which silver is used as a main ingredient. Advantageously, the invention provides an alloy bonding wire that is reliable and able to replace conventional gold alloy bonding wires. Another embodiment of the present invention provides an LED package to which is applied a silver alloy bonding wire that is capable of preventing surface discoloration (inherent in silver alloy wires) and has a high short ratio upon fabrication.

An exemplary embodiment of the present invention provides a bonding wire for semiconductor devices containing at least one element selected from the group consisting of zinc (Zn), tin (Sn), and nickel (Ni) in an amount of 5 ppm to 10 wt %, the remainder containing silver and inevitable impurities. For the purposes of this disclosure, all amounts are based on 100 wt % of the bonding wire.

The bonding wire may further contain at least one element selected from the group consisting of copper (Cu), platinum (Pt), rhodium (Rh), osmium (Os), gold, and palladium in an amount of 0.03 wt % to 10 wt %.

The bonding wire may further contain at least one element selected from the group consisting of beryllium (Be), calcium (Ca), magnesium (Mg), barium (Ba), lanthanum (La), cerium (Ce), and yttrium (Y) in an amount of 3 ppm to 5 wt %.

An LED package according to another exemplary embodiment of the present invention includes an LED chip, a lead frame for supplying power to the LED chip, and a bonding wire for connecting the LED chip and the lead frame, wherein the bonding wire is a bonding wire for semiconductor devices according to the invention.

A method of manufacturing a bonding wire for semiconductor devices according to another exemplary embodiment of the present invention includes the steps of: pouring a silver alloy, containing at least one element selected from the group consisting of zinc, tin, and nickel in an amount of 5 ppm to 10 wt %, with the remainder containing silver and inevitable impurities, into a mold and melting the silver alloy; continuously casting the melted silver alloy; and drawing the continuously casted silver alloy.

In the method of manufacturing a bonding wire for semiconductor devices, the silver alloy may further contain at least one element selected from the group consisting of copper, platinum, rhodium, osmium, gold, and palladium in an amount of 0.03 wt % to 10 wt %.

In the method of manufacturing a bonding wire for semiconductor devices, the silver alloy may further contain at least one element selected from the group consisting of beryllium, calcium, magnesium, barium, lanthanum, cerium, and yttrium in an amount of 3 ppm to 5 wt %.

The method of manufacturing a bonding wire for semiconductor devices may further include a step of performing a softening heat treatment on the drawn silver alloy.

The bonding wire for semiconductor devices of the present invention as described above uses a silver alloy bonding wire containing silver as a main ingredient, and provides high productivity, prevents surface discoloration, and has excellent reliability and mechanical characteristics.

### BRIEF DESCRIPTION OF THE SEVERAL VIEWS OF THE DRAWINGS

The foregoing summary, as well as the following detailed description of the invention, will be better understood when read in conjunction with the appended drawing. For the purpose of illustrating the invention, there are shown in the drawing embodiments which are presently preferred. It should be understood, however, that the invention is not limited to the precise arrangements and instrumentalities shown.

In the drawing:

FIG. 1 is a schematic of an LED package according to an embodiment of the invention to which a silver alloy bonding wire according to an embodiment of the invention is applied.

### DETAILED DESCRIPTION OF THE INVENTION

A bonding wire for semiconductor devices according to an exemplary embodiment of the present invention is described in detail below with reference to the accompanying drawing. For reference, in describing the present invention, a detailed description of the known functions and constructions will be omitted if it is deemed to make the gist of the present invention unnecessarily vague.

The bonding wire for semiconductor devices according to the exemplary embodiment of the present invention contains at least one element selected from the group consisting of zinc, tin, and nickel in an amount of at 5 ppm to 10 wt %, the remainder containing silver and inevitable impurities.

The bonding wire for semiconductor devices may further contain at least one element selected from the group consisting of copper, platinum, rhodium, osmium, gold, and palladium in an amount of 0.03 wt % to 10 wt %.

The bonding wire for semiconductor devices may further contain at least one element selected from the group consisting of beryllium, calcium, magnesium, barium, lanthanum, cerium, and yttrium in an amount of 3 ppm to 5 wt %.

Silver, which is the base material forming the bonding wire according to the present invention, preferably has a degree of purity of 99.99 wt % (four-nine grade) or higher.

Silver has excellent electrical conductivity and a face centered cubic (FCC) structure. Silver can reduce costs when fabricating a bonding wire because it can replace gold, which is commonly used in conventional bonding wires.

The relative amounts of the alloying elements in the silver-containing bonding wire according to the invention will now be described.

### First Group Elements

The first group elements include zinc, tin, and nickel. In semiconductor devices, a silver bonding wire or a silver alloy bonding wire is connected to the pad of a semiconductor chip. At the time of bonding, the silver bonding wire or the silver alloy bonding wires may be easily discolored due to influences of the external environment. Accordingly, the first group elements according to the present invention function to prevent this surface discoloration.

Various experiments have shown that when the first group elements are included in the alloy in amounts of less than 5 ppm, surface discoloration, low drawability, and low reliability characteristics are observed. In contrast, when the first group elements are included in amounts of 0.01 to 10 wt %, no surface discoloration and excellent drawability and reliability characteristics are obtained. Accordingly, the preferred content of the first group elements is 5 ppm to 10 wt %.

### Second Group Elements

The second group elements include copper, platinum, rhodium, osmium, gold, and palladium.

The second group elements function to raise the tensile strength at room and high temperatures and to suppress the bending or deformation of a loop shape, such as sagging or leaning, after the loop is formed. Furthermore, the second group elements function to improve drawability, thereby improving productivity.

When an ultra-low loop is formed, the second group elements function to increase tenacity by raising yield strength at a ball neck part. Accordingly, damage at the ball neck part is reduced or eliminated. Particularly, although a bonding wire has a small diameter, the breakage of the ball neck can be suppressed.

Copper has the same FCC crystalline structure as silver and functions to improve room temperature and high temperature strength, particularly shear strength, and to refine recrystallized structure.

Furthermore, copper has higher reliability at high temperatures and high humidity than rhodium or palladium, and a small amount of copper may ameliorate the effects of the rhodium and palladium. If a large amount of copper is added, however, oxidization problems may occur and a pad may be damaged because the bonding wire becomes strong.

Rhodium and palladium are included to improve the reliability and MTBA of the bonding wire. If large amounts of rhodium and palladium are added, resistance may be increased, a pad may be damaged because the bonding wire becomes strong, and the MTBA may be shortened.

Platinum, together with silver, forms a complete solid solution and may suppress the deterioration of adhesion strength of a compression ball and an aluminum pad.

If the second group elements are added in amounts of less than 0.03 wt %, there is no effect. If the second group elements exceed 10 wt %, a dimple phenomenon is generated when a free air ball is formed, making it difficult to form perfect sphere. Accordingly, the preferred content of the second group elements is 0.03 wt % to 10 wt %.

### Third Group Elements

The third group elements include beryllium, calcium, magnesium, barium, lanthanum, cerium, and yttrium.

The third group elements are uniformly distributed over silver and solid-solved therein and generate an interaction of stress in lattices, thereby improving strength at room temperature. Accordingly, the third group elements function to improve the tensile strength of the bonding wire and have an excellent effect in stabilizing a loop shape and reducing a deviation in loop height.

Beryllium and calcium deform silver crystal lattices through an enhanced solid solution. Accordingly, the beryllium and calcium can increase the mechanical strength of the bonding wire, lower the recrystalline temperature of the bonding wire, and increase the height of the loop.

If the third group elements are added in amounts of less than 3 ppm, the above effects are difficult to obtain. Conversely, if the third group elements exceed 5 wt %, there is a danger that breakage may occur at a ball neck part because the tensile strength is reduced. Accordingly, preferred content of the third group elements is 3 ppm to 5 wt %.

The bonding wire for semiconductor devices according to the present invention may contain inevitable impurities in addition to the silver and the alloy elements. However, the impurities do not limit the scope of the present invention.

An LED package according to another exemplary embodiment of the present invention may be fabricated using a bonding wire containing the first group elements to the third group elements.

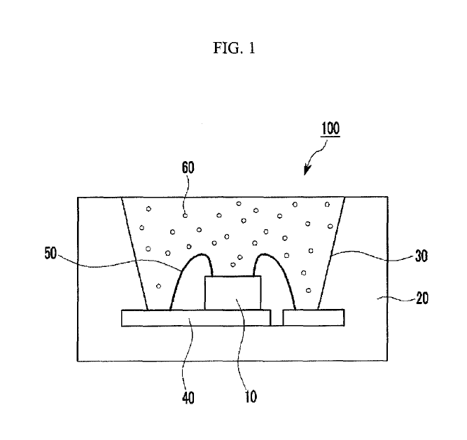

That is, as shown in FIG. 1, an LED package 100 according to the present invention includes an LED chip 10, a lead frame 20 for supplying power to the LED chip, and a bonding wire 50 for connecting the LED chip 10 and the lead frame 20.

More particularly, an LED package 100 according to the present invention includes a lead frame 20 and an LED chip 10 mounted on the bottom of a cavity 30 formed in the lead frame 20. An electrode 40 and an electrode pad on a top surface of the LED chip 10 are bonded by the bonding wire 50. A fluorescent substance 60 is coated on the inside of the cavity 30 and hardened to complete the LED package 100.

The silver alloy bonding wire containing silver as a main ingredient according to the present invention is used as the bonding wire 50.

A method of manufacturing a bonding wire for semiconductor devices according to another exemplary embodiment of the present invention includes the steps of pouring a silver alloy, containing at least one element selected from the group consisting of zinc, tin, and nickel in an amount of 5 ppm to 10 wt % and the remainder containing silver and inevitable impurities, into a mold and melting the silver alloy, continuously casting a melted silver alloy, and then drawing the continuously casted silver alloy.

The silver alloy may further contain at least one element selected from the group consisting of copper, platinum, rhodium, osmium, gold, and palladium in an amount of 0.03 wt % to 10 wt %.

The silver alloy may further contain at least one element selected from the group consisting of beryllium, calcium, magnesium, barium, lanthanum, cerium, and yttrium in an amount of 3 ppm to 5 wt %.

The method of manufacturing the bonding wire for semiconductor devices may further include a step of performing a softening heat treatment on the drawn silver alloy.

The present invention is described in more detail with reference to the method of manufacturing the bonding wire according to the present invention and the evaluation results of physical properties of the manufactured bonding wire.

### Method of Manufacturing the Silver Alloy Bonding Wire

A silver alloy containing zinc (i.e., the first group element) at 0.01 wt %, gold (i.e., the second group element) at 0.5 wt %, palladium (i.e., the second group element) at 0.5 wt %, calcium (i.e., the third group elements) at 0.005 wt %, and the remainder containing silver and inevitable impurities, was poured into a mold and then melted.

The melted silver alloy was continuously casted, drawn, and then subjected to a softening heat treatment in order to soften the bonding wire that was hardened by the drawing.

In a pressure chamber test used to evaluate the reliability of the bonding wire, chamber conditions included a temperature of 85° C., a pressure of 2 atmospheres, relative humidity of 85%, and a voltage of 5 V for 504 hours or more.

Using these conditions, the bonding wire materials were kept and then evaluated by performing a ball pull test (BPT). At the time of the BPT, the criterion for determining lift was that breakage was not generated at a ball neck and a ball adhesion part was lifted from the pad.

In this test, when the ball lift rate was 0%, it was evaluated as being excellent. When the ball lift rate was higher than 0% to 2% or less, it was evaluated as being good. When the ball lift rate was higher than 2% to 5% or less, it was evaluated as being average, and when the ball lift rate was higher than 5%, it was evaluated as being defective.

Table 1 shows the contents of the components of the bonding wire according to the present invention. No. 1 to No. 71 are Nos. of bonding wires manufactured according to the present invention. The unit of content of each component is weight percent, and the content of silver (Ag) refers to the remaining balance (Bal).

TABLE 1

| No | Ag | Zn | Sn | Ni | Cu | Pt | Rh | Os | Au | Pd | Be | Ca | Mg | Ba | La | Ce | Y |
|---|---|---|---|---|---|---|---|---|---|---|---|---|---|---|---|---|---|
| 1 | Bal. | 0.001 | — | — | — | | | | | | | | | | | | |
| 2 | Bal. | 0.01 | | | | | | | | | | | | | | | |
| 3 | Bal. | 0.05 | | | | | | | | | | | | | | | |
| 4 | Bal. | 0.10 | | | | | | | | | | | | | | | |
| 5 | Bal. | 0.50 | | | | | | | | | | | | | | | |
| 6 | Bal. | 1.00 | | | | | | | | | | | | | | | |
| 7 | Bal. | 5.00 | | | | | | | | | | | | | | | |
| 8 | Bal. | 10.00 | | | | | | | | | | | | | | | |
| 9 | Bal. | | 0.001 | | | | | | | | | | | | | | |
| 10 | Bal. | | 0.01 | | | | | | | | | | | | | | |
| 11 | Bal. | | 0.05 | | | | | | | | | | | | | | |
| 12 | Bal. | | 0.10 | | | | | | | | | | | | | | |
| 13 | Bal. | | 0.50 | | | | | | | | | | | | | | |
| 14 | Bal. | | 1.00 | | | | | | | | | | | | | | |
| 15 | Bal. | | 5.00 | | | | | | | | | | | | | | |
| 16 | Bal. | | 10.00 | | | | | | | | | | | | | | |
| 17 | Bal. | | | 0.001 | | | | | | | | | | | | | |
| 18 | Bal. | | | 0.01 | | | | | | | | | | | | | |
| 19 | Bal. | | | 0.05 | | | | | | | | | | | | | |
| 20 | Bal. | | | 0.10 | | | | | | | | | | | | | |
| 21 | Bal. | | | 0.50 | | | | | | | | | | | | | |
| 22 | Bal. | | | 1.00 | | | | | | | | | | | | | |
| 23 | Bal. | | | 5.00 | | | | | | | | | | | | | |
| 24 | Bal. | | | 10.00 | | | | | | | | | | | | | |
| 25 | Bal. | | | | 0.03 | | | | | | | | | | | | |
| 26 | Bal. | | | | 0.05 | | | | | | | | | | | | |
| 27 | Bal. | | | | 0.1 | | | | | | | | | | | | |
| 28 | Bal. | | | | 0.5 | | | | | | | | | | | | |
| 29 | Bal. | | | | 1 | | | | | | | | | | | | |
| 30 | Bal. | | | | 5 | | | | | | | | | | | | |
| 31 | Bal. | | | | 10 | | | | | | | | | | | | |
| 32 | Bal. | | | | | 0.1 | | | | | | | | | | | |
| 33 | Bal. | | | | | 1 | | | | | | | | | | | |
| 34 | Bal. | | | | | | 1 | | | | | | | | | | |
| 35 | Bal. | | | | | | | 1 | | | | | | | | | |
| 36 | Bal. | | | | | | | | 0.5 | | | | | | | | |
| 37 | Bal. | | | | | | | | 1 | | | | | | | | |
| 38 | Bal. | | | | | | | | 5 | | | | | | | | |
| 39 | Bal. | | | | | | | | | 0.01 | | | | | | | |
| 40 | Bal. | | | | | | | | | 0.05 | | | | | | | |
| 41 | Bal. | | | | | | | | | 0.1 | | | | | | | |
| 42 | Bal. | | | | | | | | | 0.5 | | | | | | | |
| 43 | Bal. | | | | | | | | | 1 | | | | | | | |
| 44 | Bal. | | | | | | | | | 5 | | | | | | | |
| 45 | Bal. | | | | | | | | | 10 | | | | | | | |
| 46 | Bal. | | | | | | | | | | 0.001 | | | | | | |
| 47 | Bal. | | | | | | | | | | | 0.001 | | | | | |
| 48 | Bal. | | | | | | | | | | | 0.005 | | | | | |
| 49 | Bal. | | | | | | | | | | | 0.01 | | | | | |
| 50 | Bal. | | | | | | | | | | | 0.05 | | | | | |
| 51 | Bal. | | | | | | | | | | | | 0.001 | | | | |
| 52 | Bal. | | | | | | | | | | | | | 0.001 | | | |
| 53 | Bal. | | | | | | | | | | | | | | 0.001 | | |
| 54 | Bal. | | | | | | | | | | | | | | | 0.001 | |
| 55 | Bal. | | | | | | | | | | | | | | | | 0.001 |
| 56 | Bal. | 0.01 | | | 0.03 | | | | | | | | | | | | |
| 57 | Bal. | 0.05 | | | 0.05 | | | | | | | | | | | | |
| 58 | Bal. | 0.10 | | | 0.1 | | | | | | | | | | | | |
| 59 | Bal. | 0.50 | | | 0.5 | | | | | | | | | | | | |
| 60 | Bal. | 1.00 | | | 1 | | | | | | | | | | | | |
| 61 | Bal. | | 0.05 | | | | | | 0.5 | | | | | | | | |
| 62 | Bal. | | 0.10 | | | | | | 1 | | | | | | | | |
| 63 | Bal. | | 0.50 | | | | | | 5 | | | | | | | | |
| 64 | Bal. | | 1.00 | | | | | | 10 | | | | | | | | |
| 65 | Bal. | | | 0.05 | | | | | | 0.05 | | | | | | | |
| 66 | Bal. | | | 0.10 | | | | | | 0.1 | | | | | | | |
| 67 | Bal. | | | 0.50 | | | | | | 0.5 | | | | | | | |
| 68 | Bal. | | | 1.00 | | | | | | 1 | | | | | | | |
| 69 | Bal. | 0.01 | | | | | | | 0.5 | 0.5 | | 0.005 | | | | | |
| 70 | Bal. | | | 0.01 | | | | | 5 | 1 | | | | | | | 0.01 |
| 71 | Bal. | | 0.1 | | 0.03 | | | | 0.5 | 0.5 | | | | | | 0.01 | |

In Table 1, Nos. 1 to 8 are bonding wires manufactured by changing the content of zinc (i.e., a first group element), Nos. 9 to 16 are bonding wires manufactured by changing the content of tin (i.e., a first group element), and Nos. 17 to 24 are bonding wires manufactured by changing the content of nickel.

Furthermore, Nos. 25 to 31 are bonding wires manufactured by changing the content of copper (i.e., a second group element), Nos. 32 and 33 are bonding wires manufactured by changing the content of platinum (i.e., a second group elements), Nos. 34 and 35 are bonding wires manufactured by adding rhodium and osmium (i.e., second group elements), respectively, Nos. 36 to 38 are bonding wires manufactured by changing the content of gold (i.e., a second group element), and Nos. 39 to 45 are bonding wires manufactured by changing the content of palladium (i.e., a second group element).

No. 46 is a bonding wire manufactured by adding beryllium (i.e., a third group element), Nos. 47 to 50 are bonding wires manufactured by changing the content of calcium (i.e., a third group element), and Nos. 51 to 55 are bonding wires manufactured by adding magnesium, barium, lanthanum, cerium, and yttrium (i.e., third group elements), respectively.

Nos. 56 to 60 are bonding wires manufactured by changing the contents of zinc (i.e., a first group element) and copper (i.e., a second group element), Nos. 61 to 64 are bonding wires manufactured by changing the contents of tin (i.e., a first group element) and gold (i.e., a second group element), and Nos. 65 to 68 are bonding wires manufactured by changing the contents of nickel (i.e., a first group element) and palladium (i.e., a second group element).

No. 69 is a bonding wire containing zinc (i.e., a first group element), gold, palladium (i.e., second group elements), and calcium (i.e., a third group element). No. 70 is a bonding wire containing nickel (i.e., a first group element), gold, palladium (i.e., second group elements), and yttrium (i.e., a third group elements). No. 71 is a bonding wire containing tin (i.e., a first group element), copper, gold, palladium (i.e., second group elements), and cerium (i.e., a third group element).

Table 2 below shows the evaluation results of the physical characteristics of the bonding wires according to the present invention shown in Table 1.

TABLE 2

| | | | Ball pull test | | | Tensile | | | | Shelf |
|---|---|---|---|---|---|---|---|---|---|---|
| | Surface | FAB | Before | After | | strength | Resistivity | | Hardness | life |
| No. | discoloration | shape | PCT | PCT | Reliability | (g) | (μΩcm) | Drawability | (Hv) | (days) |
| 1 | Δ | Δ | 7.5 | 1.8 | X | 13.5 | 1.7 | 1.6 | 63 | 32 |
| 2 | ⊚ | Δ | 9 | 2 | X | 13.8 | 1.7 | 0.06 | 64 | 256 |
| 3 | ⊚ | Δ | 9.5 | 8.4 | ⊚ | 14 | 1.7 | 0.06 | 64 | 256 |
| 4 | ⊚ | Δ | 9.6 | 9.2 | ⊚ | 14.5 | 1.8 | 0.05 | 65 | 256 |
| 5 | ⊚ | Δ | 9.7 | 9.4 | ⊚ | 15.7 | 2.2 | 0.05 | 65 | 256 |
| 6 | ⊚ | Δ | 10.2 | 9.5 | ⊚ | 18 | 2.8 | 0.05 | 66 | 256 |
| 7 | Δ | X | 12.5 | 8.4 | Δ | 23 | 4.7 | 1.6 | 80 | 32 |
| 8 | Δ | X | 12.9 | 8.3 | Δ | 28 | 5 | 1.6 | 90 | 32 |
| 9 | Δ | Δ | 7 | 1.5 | X | 12 | 1.7 | 1.6 | 63 | 32 |
| 10 | ⊚ | Δ | 8.2 | 1.9 | X | 12.5 | 1.7 | 0.06 | 64 | 256 |
| 11 | ⊚ | Δ | 9.2 | 8.2 | ⊚ | 13 | 1.7 | 0.06 | 64 | 256 |
| 12 | ⊚ | Δ | 10 | 9.1 | ⊚ | 14 | 1.8 | 0.05 | 65 | 256 |
| 13 | ⊚ | Δ | 10.3 | 9.3 | ⊚ | 15 | 2.2 | 0.05 | 65 | 256 |
| 14 | ⊚ | Δ | 10.6 | 9.4 | ⊚ | 17 | 2.8 | 0.05 | 66 | 256 |
| 15 | Δ | X | 11.1 | 8.5 | Δ | 21 | 4.7 | 1.6 | 74 | 32 |
| 16 | Δ | X | 11.6 | 8.2 | Δ | 26 | 5 | 1.6 | 74 | 32 |
| 17 | Δ | Δ | 8 | 2 | X | 14.3 | 1.7 | 1.32 | 63 | 32 |
| 18 | ⊚ | Δ | 9.5 | 2.1 | X | 14.5 | 1.7 | 0.25 | 64 | 256 |
| 19 | ⊚ | Δ | 10 | 8.5 | ⊚ | 15 | 1.7 | 0.25 | 64 | 256 |
| 20 | ⊚ | Δ | 11.3 | 9.5 | ⊚ | 17.2 | 1.8 | 0.25 | 64 | 256 |
| 21 | ⊚ | Δ | 11.7 | 9.5 | ⊚ | 17.5 | 2.2 | 0.3 | 64 | 256 |
| 22 | ⊚ | Δ | 12.3 | 9.6 | ⊚ | 18 | 2.8 | 0.3 | 64 | 256 |
| 23 | Δ | X | 13.4 | 8.5 | Δ | 26 | 4.7 | 1.32 | 66 | 256 |
| 24 | Δ | X | 14.8 | 8.4 | Δ | 30 | 5 | 1.6 | 74 | 256 |
| 25 | ⊚ | Δ | 10.3 | 1.4 | X | 14 | 1.7 | 2 | 63 | 32 |
| 26 | ⊚ | Δ | 10.5 | 1.5 | X | 14.3 | 1.7 | 1.68 | 63 | 32 |
| 27 | ⊚ | Δ | 11.2 | 2.6 | X | 15.3 | 1.7 | 0.03 | 65 | 128 |
| 28 | ⊚ | Δ | 11.2 | 2.6 | X | 15.3 | 1.7 | 0.03 | 66 | 128 |
| 29 | X | X | 11.3 | 2.6 | X | 15.5 | 1.7 | 0.03 | 66 | 128 |
| 30 | X | X | 12.1 | 2.4 | Δ | 21 | 4.3 | 0.04 | 67 | 128 |
| 31 | X | X | 13.5 | 2.4 | Δ | 27 | 10.5 | 0.06 | 74 | 128 |
| 32 | ⊚ | Δ | 11.4 | 2.8 | ⊚ | 15 | 1.7 | 1.1 | 65 | 32 |
| 33 | ⊚ | Δ | 12 | 2.7 | ⊚ | 16 | 2.5 | 0.9 | 66 | 32 |
| 34 | ⊚ | Δ | 10.9 | 2.4 | ⊚ | 14 | 2.5 | 1.5 | 66 | 32 |
| 35 | ⊚ | Δ | 10.5 | 2.3 | ⊚ | 15 | 2.5 | 1.5 | 67 | 32 |
| 36 | ⊚ | Δ | 10.3 | 9.3 | ⊚ | 14 | 1.7 | 1.9 | 64 | 32 |
| 37 | ⊚ | Δ | 11 | 9.8 | ⊚ | 15 | 1.7 | 1.9 | 65 | 256 |
| 38 | ⊚ | Δ | 11.9 | 10.7 | ⊚ | 17 | 3 | 2 | 67 | 256 |
| 39 | ⊚ | Δ | 10.5 | 1.5 | X | 14.3 | 1.7 | 1.51 | 63 | 32 |
| 40 | ⊚ | Δ | 10.7 | 9.5 | ⊚ | 16.2 | 1.8 | 0.13 | 64 | 128 |
| 41 | ⊚ | Δ | 10.8 | 9.8 | ⊚ | 17 | 1.8 | 0.1 | 64 | 256 |
| 42 | ⊚ | Δ | 11 | 10 | ⊚ | 17.3 | 2 | 0.1 | 64 | 256 |
| 43 | ◯ | Δ | 11.2 | 10.2 | ⊚ | 17.5 | 2.9 | 0.09 | 65 | 256 |
| 44 | ◯ | Δ | 12 | 10.9 | ⊚ | 21 | 4.5 | 0.1 | 66 | 256 |
| 45 | Δ | Δ | 12.4 | 6.3 | ◯ | 27.5 | 10.8 | 1.56 | 70 | 256 |
| 46 | ⊚ | Δ | 8 | 1.4 | ⊚ | 13 | 1.7 | 2.2 | 63 | 32 |
| 47 | ⊚ | Δ | 12.4 | 2.2 | X | 16 | 1.7 | 0.04 | 64 | 32 |
| 48 | ⊚ | Δ | 12.6 | 2.1 | X | 17.8 | 1.7 | 0.04 | 65 | 128 |
| 49 | ⊚ | Δ | 12.9 | 1.9 | X | 18.1 | 1.7 | 0.07 | 66 | 128 |
| 50 | ⊚ | Δ | 12.9 | 1.5 | X | 18.2 | 1.8 | 1.74 | 71 | 128 |
| 51 | ⊚ | Δ | 9 | 1.5 | X | 15 | 1.7 | 2 | 63 | 32 |
| 52 | ⊚ | Δ | 8.2 | 1.3 | X | 13 | 1.7 | 3 | 63 | 32 |
| 53 | ⊚ | Δ | 10 | 1.6 | X | 14 | 1.7 | 1.7 | 63 | 32 |
| 54 | ⊚ | Δ | 8.8 | 1.5 | X | 15 | 1.7 | 2.4 | 63 | 32 |
| 55 | ⊚ | Δ | 8.5 | 1.4 | X | 16 | 1.7 | 1 | 63 | 32 |
| 56 | ⊚ | Δ | 10.3 | 1.3 | X | 14 | 1.7 | 2 | 63 | 32 |
| 57 | ⊚ | Δ | 10.5 | 1.6 | X | 14.3 | 1.7 | 1.68 | 63 | 128 |
| 58 | ⊚ | Δ | 11.2 | 2.7 | X | 15.3 | 1.7 | 0.03 | 65 | 128 |
| 59 | ⊚ | Δ | 11.2 | 2.7 | X | 15.3 | 1.7 | 0.03 | 66 | 128 |
| 60 | ◯ | Δ | 11.3 | 2.7 | X | 15.5 | 1.9 | 0.03 | 66 | 128 |
| 61 | ⊚ | Δ | 10.3 | 9.3 | ⊚ | 14 | 1.7 | 1.9 | 65 | 32 |
| 62 | ⊚ | Δ | 11 | 9.8 | ⊚ | 15 | 1.7 | 1.9 | 66 | 256 |
| 63 | ⊚ | Δ | 11.9 | 10.7 | ⊚ | 17 | 3 | 2 | 68 | 256 |
| 64 | ⊚ | Δ | 13 | 12 | ⊚ | 21 | 4.7 | 3 | 72 | 256 |
| 65 | ⊚ | Δ | 10.9 | 9.6 | ⊚ | 16.7 | 1.7 | 0.12 | 64 | 128 |
| 66 | ⊚ | Δ | 11 | 9.9 | ⊚ | 17.2 | 1.7 | 0.17 | 64 | 256 |
| 67 | ⊚ | Δ | 11.3 | 10.2 | ⊚ | 17.8 | 2 | 0.19 | 67 | 256 |
| 68 | ◯ | Δ | 11.6 | 10.5 | ⊚ | 18.5 | 2.9 | 0.2 | 69 | 256 |
| 69 | ⊚ | Δ | 10.7 | 9.6 | ⊚ | 15.2 | 1.8 | 2.3 | 65 | 128 |
| 70 | ⊚ | Δ | 11.2 | 10.2 | ⊚ | 15.9 | 3 | 1.9 | 67 | 256 |
| 71 | ⊚ | Δ | 10.8 | 9.8 | ⊚ | 15.4 | 1.8 | 2.2 | 66 | 128 |

In Table 2, surface discoloration is measured based on the reflectivity of the wire, wherein ⊚ indicates an excellent state, ∘ is a good state, Δ is a normal state, and X is a bad state.

FAB is an abbreviation for a free air ball. A circular FAB for performing ball bonding can be formed at the wire tail at the capillary tip by using EFO discharge after secondary bonding. Here, regarding the formed FAB shape, a perfect sphere is indicated by an excellent state. A case where the formed FAB shape has a perfect sphere but is slightly deviated from the center of the wire is indicated by a good state. A case where the formed FAB shape is slightly deviated from a perfect sphere and the center of the wire is indicated by a normal state. A case of a tilted ball (a FAB severely deviated from the center of the wire) and bonding not possible for the formed FAB shape is indicated by a bad state. The FAB shape characteristics are indicated with the same meaning as the marks for the surface discoloration

High humidity reliability is indicated by adhesion strength (a BPT value) in a pressure cooker test (PCT). The silver alloy wire had a diameter of 30 μm, and the PCT was performed at 121° C. for about 96 hours. In reliability of adhesion strength, ⊚ indicates an excellent state, ∘ indicates a quite excellent state, Δ indicates a normal state, and X indicates a bad state.

Processability was measured by the number of disconnected wires per 1 km of the silver alloy wire. Processability is better when values are lower.

Shelf life, the time that it took for a 100 nm thick oxide layer to be formed in the silver alloy wire, is indicated by a date. The shelf life is better with higher values.

From Tables 1 to 2, it can be seen that zinc, tin, and nickel contents (i.e., the first group elements) influence the surface discoloration of the silver alloy wire in Nos. 1 to 24.

It can be seen that in Nos. 1 to 24, the silver alloy wire has excellent surface discoloration, drawability, and reliability with zinc, tin, and nickel contents of 0.01 to 10 wt %, and the FAB shape characteristic is influenced by zinc, tin, and nickel contents of 5 wt % or higher.

It can be seen that in Nos. 25 to 31, copper content (i.e., the second group elements) influences the surface discoloration of the silver alloy wire. When the copper content is less than 1%, the surface discoloration of the silver alloy wire is excellent. When the copper content is 0.1% or higher, excellent processability starts to show.

On the other hand, it can be seen that the reliability and FAB shape of the silver alloy wire are adversely affected.

It can be seen that in Nos. 36 to 45, gold and palladium contents (i.e., the second group elements) have an excellent effect on the reliability and surface discoloration of the silver alloy wire, with the palladium content having a better characteristic in terms of processability.

In Nos. 51 to 55, magnesium, barium, lanthanum, cerium, and yttrium (i.e., the third group elements) reveal adhesion strength and drawing characteristics of the silver alloy wire.

In Nos. 56 to 60, the characteristics of an alloy containing zinc and copper are shown. It can be seen that adhesion strength is increased and the drawing characteristic becomes better with an increase in zinc and copper contents.

In Nos. 61 to 64, the characteristics of an alloy containing tin and gold are shown. It can be seen that drawing is excellent with a decrease of tin and gold contents, and that adhesion strength and shelf life are increased with an increase of tin and gold.

In Nos. 65 to 68, the characteristics of an alloy containing nickel and palladium are shown. It can be seen that strength is improved with an increase in nickel and palladium contents, and the drawing characteristic and strength of palladium are improved.

In Nos. 69 to 71, the characteristics of a silver alloy wire made of a ternary (or higher) alloy containing gold and palladium are shown. If the gold and palladium contents are increased, adhesion strength and drawing characteristics become excellent, but the electrical characteristic tends to decrease. If gold and palladium are included, reliability is excellent and the shelf life is increased.

It will be appreciated by those skilled in the art that changes could be made to the embodiments described above without departing from the broad inventive concept thereof. It is understood, therefore, that this invention is not limited to the particular embodiments disclosed, but it is intended to cover modifications within the spirit and scope of the present invention as defined by the appended claims.

We claim:

1. A bonding wire for semiconductor devices, comprising at least one element selected from the group consisting of zinc (Zn), tin (Sn), and nickel (Ni) in an amount of 5 ppm to 10 wt %; wherein a remainder of the bonding wire comprises silver (Ag) and inevitable impurities.

2. The bonding wire of claim 1, further comprising at least one element selected from the group consisting of copper (Cu), platinum (Pt), rhodium (Rh), osmium (Os), gold (Au), and palladium (Pd) in an amount of 0.03 wt % to 10 wt %.

3. The bonding wire of claim 1, further comprising at least one element selected from the group consisting of beryllium (Be), calcium (Ca), magnesium (Mg), barium (Ba), lanthanum (La), cerium (Ce), and yttrium (Y) in an amount of 3 ppm to 5 wt %.

4. A light emitting diode (LED) package comprising an LED chip, a lead frame, and a bonding wire, wherein the lead frame supplies power to the LED chip, and wherein the bonding wire connects the LED chip and the lead frame and is a bonding wire for semiconductor devices according to claim 1.

5. A method of manufacturing a bonding wire for semiconductor devices, comprising the steps of:
pouring a silver (Ag) alloy into a mold and melting the silver alloy, wherein the silver alloy comprises at least one element selected from the group consisting of zinc (Zn), tin (Sn), and nickel (Ni) in an amount of 5 ppm to 10 wt %, and wherein the remainder of the alloy comprises silver (Ag) and inevitable impurities;
continuously casting the melted silver alloy; and
drawing the continuously casted silver alloy.

6. The method of claim 5, wherein the silver alloy further comprises at least one element selected from the group consisting of copper (Cu), platinum (Pt), rhodium (Rh), osmium (Os), gold (Au), and palladium (Pd) in an amount of 0.03 wt % to 10 wt %.

7. The method of claim 5, wherein the silver alloy further comprises at least one element selected from the group consisting of beryllium (Be), calcium (Ca), magnesium (Mg), barium (Ba), lanthanum (La), cerium (Ce), and yttrium (Y) in an amount of 3 ppm to 5 wt %.

8. The method of claim 7, further comprising a step of performing a softening heat treatment on the drawn silver alloy.
